(19) United States
(12) Patent Application Publication
(10) Pub. No.: US 2013/0027148 A1
(43) Pub. Date: Jan. 31, 2013

(54) ANTIRESONANT FREQUENCY-VARYING COMPLEX RESONANT CIRCUIT

(71) Applicant: Koichi Hirama, Hiratsuka-shi (JP)

(72) Inventor: Koichi Hirama, Hiratsuka-shi (JP)

(73) Assignee: MARCDEVICES CO., LTD., Hiratsuka-shi, Kanagawa (JP)

(21) Appl. No.: 13/577,863

(22) PCT Filed: Feb. 7, 2011
(86) PCT No.: PCT/JP2011/052500

§ 371 Date: Oct. 5, 2012

(30) Foreign Application Priority Data
Feb. 9, 2010 (JP) 2010-026491

(51) Int. Cl. H03L 1/00

(52) U.S. Cl. 331/175; 331/185

(57) ABSTRACT

A complex resonant circuit includes: a first current path performing a first gain control to an AC power signal being supplied; at least one second current path performing a second gain control different from the first gain control to the AC power signal; at least two resonant circuits provided on the respective first and second current paths, having mutually different resonance or antiresonance points for the AC power signals passing through the respective first and second current paths and capturing the respective AC power signals; at least one compensation current path performing a compensation phase shift to the AC power signal; a compensation circuit, provided on the compensation current path, for removing an unnecessary component of the resonant circuit; and an analog operational circuit performing analog addition or subtraction on the AC power signal having passed through the first and second current paths, and the compensation current path.

### TECHNICAL FIELD

The present invention relates to an antiresonant frequency-varying complex resonant circuit which enables a variable antiresonant frequency range to be flexibly set.

### BACKGROUND ART

For electronic components which utilize the natural resonant frequency of, e.g., piezoelectric oscillators, a method for connecting reactive elements such as capacitors in parallel is well-known as means for varying the zero phase frequency, i.e., the antiresonant frequency thereof; however, the frequency range itself cannot be varied by changing the physical constants such as of the piezoelectric oscillators. As a result, an attempt to make a wide frequency variable range available would result in degradation in output itself.

Disclosed in Patent Literature 1 is a circuit for varying the frequency, which gives a relative minimum power at a power summing point, by controlling the ratio of voltages to be applied to a resonant circuit that includes two series resonant circuits. In this circuit, the frequency range with two series resonant frequencies at the respective ends can be arbitrarily controlled by varying the voltage ratio being applied. However, at the center of the variable frequency range, there occurs an extreme deterioration in the effective resonance quality factor Q value which is computed from the frequency range (3 dB bandwidth), in which the effective value of power is twice that at a relative minimum, based on the performance at the relative minimum, that is, the relation between the effective value of power at the relative minimum and the frequency.

Furthermore, the effective Q values at the ends of the variable frequency range suffer, in practice, significant deterioration when compared with the resonance quality factor Q value without load on the crystal oscillator.

Means for cancelling the parallel capacitance of the crystal oscillator which restricts the variable frequency range is disclosed in Patent Literature 2; however, the means cannot provide a wide variable frequency range.

Disclosed in Non-Patent Literature 1 is an approach which allows an oscillator circuit for outputting one fixed frequency to provide an improved effective resonance quality factor Q value as a whole bridge circuit by placing a crystal oscillator on one side of the bridge and selecting arbitrary circuit components on the other sides. However, the frequency cannot be varied over a wide band.

In summary, conventional complex resonant circuits provided only undesirable performances in practice: the operative resonance quality factor Q value was greatly varied over the entirety of a wide variable frequency range; and significant deterioration was found in the resonance quality factor Q value when compared with the resonance quality factor Q value of the employed resonance element itself.

### CITATION LIST

### Patent Literature

PTL 1: International Publication No. 2006/046672

PTL 2: Japanese Patent Kokai No. H8-204451

### Non-Patent Literature

NPL 1: W. R. Sooy, F. L. Vernon, and J. Munushian: “A Microwave Meacham Bridge Oscillator”, Proc. IRE, Vol. 48, No. 7, pp. 1297-1306, July 1960

### SUMMARY OF INVENTION

### Technical Problem

It is an object of the present invention to provide an antiresonant frequency-varying complex resonant circuit which enables a complex resonant circuit with an oscillator, such as a piezoelectric oscillator, having a good resonance quality factor to achieve a value close to the resonance quality factor Q value with the employed resonance element unloaded and set an antiresonant variable frequency range with a high degree of flexibility over a wide frequency range.

### Solution to Problem

To address the aforementioned problems, the antiresonant frequency-varying complex resonant circuit according to the present invention includes: a first current path on which first gain control is provided to an AC power signal being supplied; at least one second current path on which second gain control different in an amount of control from the first gain control is provided to the AC power signal; at least two resonant circuits which are provided each on the respective first and second current paths and which have mutually different resonance points or antiresonance points for the AC power signals passing through the respective first and second current paths and capture the respective AC power signals; at least one compensation current path on which a compensation phase shift is provided to the AC power signal; a compensation circuit, provided on the compensation current path, for removing an unnecessary component of the resonant circuit; and an analog operational circuit for performing analog addition or subtraction on the AC power signal having passed through the first current path, the second current path, and the compensation current path.

### Advantageous Effects of Invention

According to the complex resonant circuit of the present invention, a resonance variable frequency range can be set with a high degree of flexibility over a desired variable frequency range without deterioration in effective resonance quality factor Q value.

### BRIEF DESCRIPTION OF DRAWINGS

FIG. 1 is a circuit diagram illustrating a complex resonant circuit according to a first embodiment of the present invention.

FIG. 2 is an explanatory view illustrating the effects of the first embodiment of the present invention.

FIG. 3 is a circuit diagram illustrating a complex resonant circuit according to a second embodiment of the present invention.

FIG. 4 is a view illustrating an example of frequency characteristics according to a conventional technique.

FIG. 5 is a view illustrating an example of frequency characteristics for which compensation has been made.

FIG. 6 is an explanatory view illustrating the uniqueness of a solution to compensation characteristics.

FIG. 7 is a circuit diagram illustrating a complex resonant circuit according to a third embodiment of the present invention.

FIG. 8 is a view illustrating the simulation results of exemplary frequency characteristics for which no compensation has been provided.

FIG. 9 is a view illustrating the simulation results of exemplary frequency characteristics for which compensation has been provided.

FIG. 10 is an enlarged view illustrating an example of frequency characteristics on the lower end of a variable frequency range.

FIG. 11 is an enlarged view illustrating an example of frequency characteristics at the center of a variable frequency range.

### DESCRIPTION OF EMBODIMENTS

### First Embodiment

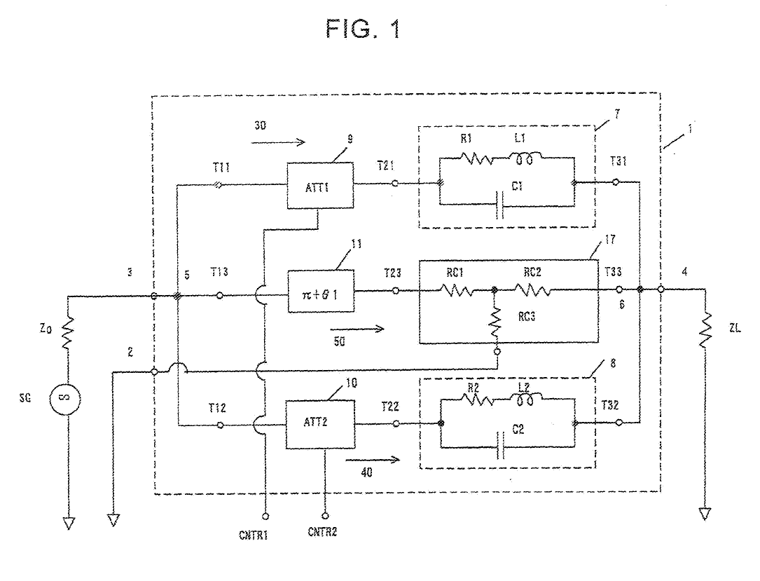

FIG. 1 shows an antiresonant frequency-varying complex resonant circuit according to a first embodiment of the present invention. As shown in FIG. 1, the antiresonant frequency-varying complex resonant circuit 1 includes: a reference terminal 2; an input terminal 3; a first attenuation circuit 9 (Attenuator: ATT1) and a second attenuation circuit (Attenuator: ATT2) for attenuating each the power level of an input signal being supplied at a frequency f from the input terminal 3 through a power distribution circuit 5 and a terminal T11 or a terminal T12 into mutually different power levels e1 and e2 and then supplying each of the signals at the respective resulting powers to a first resonator circuit 7 or a second resonator circuit 8 via a terminal T21 or a terminal T22, respectively; a first phase shift circuit 11 for providing a phase shift of π+θ1 to the power level of an input signal supplied at the frequency f from the input terminal 3 via the power distribution circuit 5 and a terminal T13 and then supplying the phase-shifted signal to a first compensation circuit 17 via a terminal T23; the first resonator circuit 7 and the second resonator circuit 8 connected via the terminal T21 or the terminal T22 to the first attenuation circuit 9 or the second attenuation circuit 10, respectively; the first compensation circuit 17 connected via the terminal T23 to the first phase shift circuit 11; a power adder circuit 6 connected via a terminal T31, a terminal T32, and a terminal T33 to the first resonator circuit 7, the second resonator circuit 8, and the first compensation circuit 17, respectively; and an output terminal 4 connected to the power adder circuit 6. Furthermore, the path from the terminal T11 to the terminal T31 is defined as a first current path 30, the path from the terminal T12 to the terminal T32 as a second current path 40, and the path from the terminal T13 to the terminal T33 as a first compensation current path 50.

Each component of the antiresonant frequency-varying complex resonant circuit 1 shown in FIG. 1 will be described in more detail. The input terminal 3 of the antiresonant frequency-varying complex resonant circuit 1 of FIG. 1 is connected to a standard signal generator SG, so that an input signal, which is maintained at a constant output and has a frequency f continuously swept, is applied to the input terminal 3 of the antiresonant frequency-varying complex resonant circuit 1. The input signal is supplied to each of the first attenuation circuit 9, the second attenuation circuit 10, and the first phase shift circuit 11 via the power distribution circuit 5, and the terminal T11, the terminal T12, and the terminal T13, respectively.

The first attenuation circuit 9 has an input terminal (not shown), an output terminal (not shown), and an external control terminal CNTR1. Control is provided through this external control terminal CNTR1, thereby allowing the first attenuation circuit 9 to vary arbitrarily the ratio of the power level at the input terminal and the power level at the output terminal and then output the signal at the resulting power from the output terminal via the terminal T21 to the first resonator circuit 7. Note that the input terminal of the first attenuation circuit 9 connects to the terminal T11.

The second attenuation circuit 10 has an input terminal (not shown), an output terminal (not shown), and an external control terminal CNTR2. Control is provided through this external control terminal CNTR2, thereby allowing the second attenuation circuit 10 to vary arbitrarily the ratio of the power level at the input terminal and the power level at output terminal and then output the signal at the resulting power from the output terminal via the terminal T22 to the second resonator circuit 8. Note that the input terminal of the second attenuation circuit 10 connects to the terminal T12.

The first phase shift circuit 11 has an input terminal (not shown) and an output terminal (not shown). The first phase shift circuit 11 provides a phase shift of (π+θ1) to an input signal, which is supplied to the input terminal via the terminal T13, and then outputs the phase-shifted signal from the output terminal via the terminal T23 to the first compensation circuit 17.

The first resonator circuit 7 connects to the terminal T21 and the terminal T31 and delivers the output therefrom to the output terminal 4 via the terminal T31 and the power adder circuit 6. The first resonator circuit 7 includes a parallel circuit which is made up of a series circuit of a coil L1 and a resistor R1 disposed between the terminal T21 and the terminal T31, and a capacitor C1 connected in parallel to the series circuit.

The second resonator circuit 8 connects to the terminal T22 and the terminal T32, and delivers the output therefrom to the output terminal 4 via the terminal T32 and the power adder circuit 6. The second resonator circuit 8 includes a parallel circuit which is made up of a series circuit of a coil L2 and a resistor R2 disposed between the terminal T22 and the terminal T32, and a capacitor C2 connected in parallel to the series circuit.

The first compensation circuit 17 connects to the terminal T23, the terminal T33, and the reference terminal 2, and delivers the output therefrom to the output terminal 4 via the terminal T33 and the power adder circuit 6. The first compensation circuit 17 is configured to have a series circuit of a resistor RC1 and a resistor RC2 disposed between the terminal T23 and the terminal T33, and a resistor RC3 disposed between the intermediate point (connection point) of the series circuit and the reference terminal 2. The first compensation circuit 17 removes a resistance component or an unnecessary component of the first resonator circuit 7 and the second resonator circuit 8. The input signal applied via such a circuit to the input terminal 3 of the antiresonant frequency-varying complex resonant circuit 1 is supplied to each of the first resonator circuit 7, the second resonator circuit 8, and the first compensation circuit 17. The power level at that time is as follows. That is, The level of power applied to each of the first resonator circuit 7, the second resonator circuit 8, and the first compensation circuit 17 is an absolute voltage value of |e1|, |e2|, and |e3|, respectively, in terms of the respective electromotive forces. Here, |e3| is the absolute value that is the same as the electromotive force of the standard signal generator SG. This is because on the first compensation current path 50, a predetermined attenuated power level is not provided. Furthermore, the phase of the first resonator circuit 7 and the second resonator circuit 8 is not shifted (i.e., the phase shift thereof is 0) relative to the input signal applied to the input terminal 3, whereas only the first compensation circuit 17 is provided with a phase shift of (π+θ1) relative to the input signal applied to the input terminal 3. Furthermore, at this time, the internal resistance at each of the terminal T21, the terminal T22, and the terminal T23 is zs1, zs2, and zs3, respectively.

That is, the first resonator circuit 7 is equivalent to a series circuit of an equivalent power supply connected to an internal resistor of a resistance value zs1, the power supply providing the absolute value of electromotive force |e1| with zero phase shift. The second resonator circuit 8 is equivalent to a series circuit of an equivalent power supply connected to an internal resistor of a resistance value zs2, the power supply providing the absolute value of electromotive force |e2| with zero phase shift. The first compensation circuit 17 is equivalent to a series circuit of an equivalent power supply connected to an internal resistor of a resistance value zs3, the power supply providing the absolute value of electromotive force |e3| with a phase shift of (π+θ1).

Now, a description will be made to a modified example of the first embodiment shown in FIG. 1. The modified embodiment (not shown) is different from the first embodiment shown in FIG. 1 in the second current path but the same in the other components. Thus, the descriptions below will be made in relation only to the second current path.

The second current path of the first embodiment was described to provide gain control to an AC power signal being supplied. The second current path of the modified example relays the AC power signal being supplied. Describing the modified example with reference to FIG. 1, the modified example is configured to allow the terminals T12 and T22 of FIG. 1 to be directly connected to each other in place of the second attenuation circuit 10 of FIG. 1. Note that in the same manner as in the circuit shown in FIG. 1, the modified example also allows for setting a resonance variable frequency range over a desired variable frequency range with a high degree of flexibility without deterioration in effective resonance quality factor Q value.

Now, a description will be made to the effects and performance of the present invention. Prior to the explanation, the term “Null frequency” will be first defined. It is an object of the present invention to provide an antiresonant frequency-varying complex resonant circuit. The resonance phenomenon of which this complex resonant circuit makes use is not what is called a resonance phenomenon but an antiresonance phenomenon. In general, the characteristics and the performance of the complex resonant circuit can be grasped by examining the operation of the circuit which has a terminal serving as the input terminal thereof and a terminal serving as the output terminal thereof connected between a “high-frequency power supply” and a “load resistance.”

The complex resonant circuit of the present invention makes use of the antiresonance phenomenon, so that the absolute value of a voltage established across the ends of the aforementioned load resistance exhibits the minimum point. The oscillation frequency at which the absolute value of an output voltage exhibits a relative minimum (also referred to as the minimum point or Null point) will be referred to as the Null frequency and denoted by fnull. The Null frequency is one of those frequencies that characterize the antiresonance phenomenon.

Now, the effects and performance of the first embodiment will be described in two steps referring to the results of numerical simulations.

In the first step, it will be described that in a method without the first compensation circuit 17 of the first embodiment, the resonance quality factor Q value at the center of a variable frequency range is significantly deteriorated. In the second step, it will be described that providing a phase shift according to the present invention causes the effective Q value at the center is significantly improved within the entire variable frequency range.

In summary, the simulation was performed at a center frequency of 10 MHz in a variable frequency range of 1000 ppm (from 9995 kHz to 10005 kHz). For this simulation, the first resonator circuit 7, the second resonator circuit 8 and the first compensation circuit 17 were given the equivalent circuit constants as shown in Table 1.

TABLE 1

| | | FIRST |
|---|---|---|
| FIRST | SECOND | COMPENSATION |
| RESONATOR CIRCUIT | RESONATOR CIRCUIT | CIRCUIT |
| f1 = 9995 kHz | f2 = 10005 kHz | RC1 = 500k Ω |
| L1 = 25 mH | L2 = 25 mH | RC2 = 500k Ω |
| C1 = 10.142258 fF | C2 = 10.121994 fF | RC3 = 10 Ω |
| R1 = 100 Ω | R2 = 100 Ω | |
| Z_{S1} = 5 kΩ | Z_{S2} = 5 kΩ | Z_{S3} = 5 kΩ |

z₁ = 5 kΩ

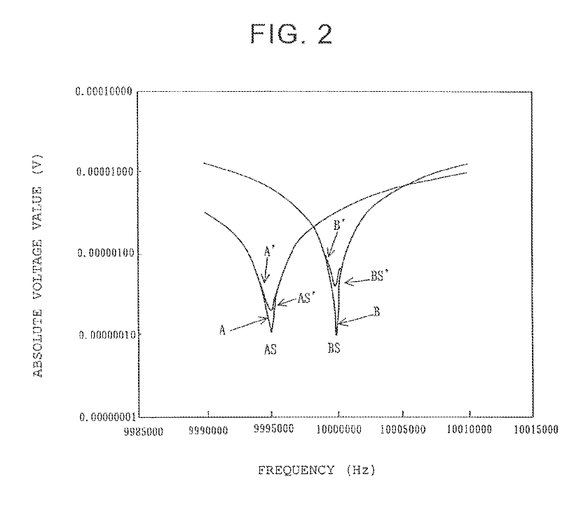

In FIG. 2, the horizontal axis represents the frequency (Hz) and the vertical axis represents the absolute value of a voltage (in volt or V) established across the ends of the load resistance zl. FIG. 2 illustrates both the results of a simulation performed by a method according to a conventional technique with the first compensation circuit 17 eliminated by applying zero voltage to the first compensation circuit 17 shown in FIG. 1 and the results of a simulation of the effects of the first embodiment with the first compensation circuit 17 included.

Since the frequency variation characteristics are substantially symmetric within the variable frequency range, FIG. 2 shows a curve A and a curve A′ at the low-frequency end thereof and a curve B and a curve B′ at the center. The two curves A′ and B′ correspond to the case with the compensation circuit unavailable, whereas the two curves A and B correspond to the case with the compensation circuit available.

The two curves A and A′ correspond to the case where the absolute value of a voltage |e1| applied to the terminal T21 and the absolute value of voltage |e2| applied to the terminal T22 are set to 1 V (1 volt) and 0 V (0 volt), respectively. The two curves B and B′ correspond to the case where the absolute value of voltage |e1| applied to the terminal T21 and the absolute value of voltage |e2| applied to the terminal T22 are set to 1 V and 1 V, respectively. Furthermore, the two curves A′ and B′ correspond to the case where the absolute value of voltage |e3| applied to the input terminal T23 of the compensation circuit is set to 0 V with a phase shift of (π+θ1). The two curves A and B correspond to the case where the absolute value of voltage |e3| applied to the input terminal T23 of the compensation circuit is set to 2^{1/2} V with a phase shift of (π+θ1). In the simulation, θ1 was set to zero. Accordingly, the phase shift was π.

A comparison between the relative minimum AS and the relative minimum AS′ showed that the relative minimum AS had dropped more significantly, and likewise, a comparison between the relative minimum BS and relative minimum BS′ showed that the relative minimum BS had dropped more significantly. This means at first glance that the resonance quality factor Q value has been improved.

That is, FIG. 2 shows that provision of the first compensation circuit 17 makes it possible to improve the steepness of a drop in the resonance curve on the low-frequency side and at the center of the variable frequency range. To vary the frequency which gives the minimum point of a resonance curve, the ratio of voltages applied to the terminal T21 and the terminal T22 is changed; however, it is pointed out that in this embodiment, the voltage applied to the compensation circuit is maintained at a constant absolute value and a constant phase shift. That is, the absolute value and the phase shift thereof need not to be varied or adjusted. This simplifies the circuit structure and provides a high practical value.

FIG. 2 shows only the low-frequency side of the variable frequency range; however, such an effect can be expected over the entire frequency range. Furthermore, by setting the constants of the compensation circuit and adjusting the absolute value of a voltage applied to the compensation circuit and the phase shift (π+θ1), the resonance quality factor Q value can be so set as to be maintained at a constant value or in a convex or concave shape over the entire frequency range.

Now, modified examples of the first embodiment will be listed below. The resistor network of the first compensation circuit 17 may be not only a T-type circuit but also a π-type circuit, or alternatively, a series connection of those circuits. Furthermore, the first compensation circuit 17 may be not only a resistor network but also an element including a reactive component. Furthermore, the arm (i.e., the first compensation current path 50) with the terminal T13, the terminal T23, and the terminal T33, which are disposed upstream and downstream of the first compensation circuit 17, may also be provided with an attenuation circuit or an amplifier circuit.

Now, an example for implementing the resonator circuit using a distributed constant circuit may be an antiresonant frequency-varying complex resonant circuit in which one end of two resonator circuits including strip line paths disposed in close proximity to each of dielectric resonators having mutually different resonance frequencies is connected to a power adder circuit so as to vary the distribution ratio (power ratio) of power to be applied to the other respective terminals of these two strip line paths.

### Second Embodiment

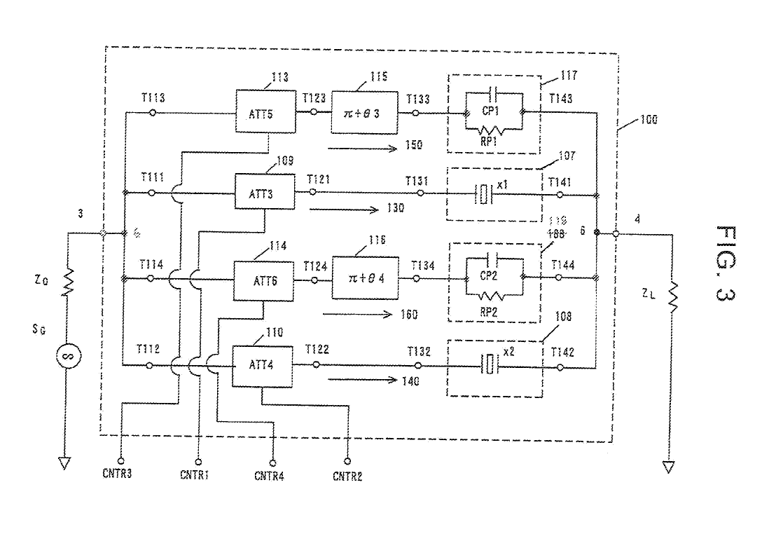

A second embodiment is configured such that the resonator circuit thereof has only two piezoelectric oscillators. This configuration has a restriction that a good performance of the resonance quality factor Q value is revealed only in the vicinity of the center of a variable frequency range, but has a feature that the resonator circuit can function in a simplified structure. FIG. 3 shows an antiresonant frequency-varying complex resonant circuit according to the second embodiment of the present invention.

The antiresonant frequency-varying complex resonant circuit 100 includes: an input terminal 3; a third attenuation circuit 109 for attenuating the power level of an input signal, which is supplied at a frequency f from the input terminal 3 via a power distribution circuit 5, into a power level e1 and then supplying the signal at the resulting power to a third resonator circuit 107 via a terminal T121 and a terminal T131; a fourth attenuation circuit 110 for attenuating the power level of an input signal, which is supplied at the frequency f from the input terminal 3 via the power distribution circuit 5, into a power level e2, and then supplying the signal at the resulting power to a fourth resonator circuit 108 via a terminal T122 and a terminal T132; a fifth attenuation circuit 113 for attenuating the power level of an input signal, which is supplied at the frequency f from the input terminal 3 via the power distribution circuit 5, into a power level e3, and then supplying the signal at the resulting power to a second phase shift circuit 115 via a terminal T123; and a sixth attenuation circuit 114 for attenuating the power level of an input signal, which is supplied at the frequency f from the input terminal 3 via the power distribution circuit 5, into a power level e4, and then supplying the signal at the resulting power to a third phase shift circuit 116 via a terminal T124. Note that power levels e1, e2, e3, and e4 are different from each other.

Furthermore, the antiresonant frequency-varying complex resonant circuit 100 includes the second phase shift circuit 115 for providing a phase shift of (π+θ3) to a signal supplied at the frequency f from the fifth attenuation circuit 113 and then supplying the phase-shifted signal to a second compensation circuit 117 via a terminal T133; and the third phase shift circuit 116 for providing a phase shift of (π+θ4) to a signal supplied at the frequency f from the sixth attenuation circuit 114, and then supplying the phase-shifted signal to a third compensation circuit 118 via a terminal T134. Note that the phase shifts (π+θ3) and (π+θ4) are different from each other.

Furthermore, the antiresonant frequency-varying complex resonant circuit 100 includes the third resonator circuit 107 connected to the third attenuation circuit 109 via the terminal T121 and the terminal T131; the fourth resonator circuit 108 connected to the fourth attenuation circuit 110 via the terminal T122 and the terminal T132; the second compensation circuit 117 connected to the second phase shift circuit 115 via the terminal T133; the third compensation circuit 118 connected to the third phase shift circuit 116 via the terminal T134; a power adder circuit 6 connected to each of the terminals T141, T142, T143, and T144; and an output terminal 4 connected to the power adder circuit 6.

Each component of the antiresonant frequency-varying complex resonant circuit 100 shown in FIG. 3 will be described in more detail below. The input terminal 3 of the antiresonant frequency-varying complex resonant circuit 100 of FIG. 3 is connected to the standard signal generator SG, so that an input signal, which is maintained at a constant output and has a frequency f continuously swept, is applied to the input terminal 3 of the antiresonant frequency-varying complex resonant circuit 100.

The input signal applied to the input terminal 3 is supplied to the third attenuation circuit 109, the fourth attenuation circuit 110, the fifth attenuation circuit 113, and the sixth attenuation circuit 114 via the power distribution circuit 5, and the terminal T111, the terminal T112, the terminal T113, or the terminal T114.

The third attenuation circuit 109 has an input terminal (not shown), an output terminal (not shown), and an external control terminal CNTR1. Controlling the external control terminal CNTR1 would allow the third attenuation circuit 109 to arbitrarily vary the ratio of the power level at the input terminal and the power level at the output terminal and then output the signal at the resulting power from the output terminal via the terminal T121 and the terminal T131 to the third resonator circuit 107. Note that the input terminal of the third attenuation circuit 109 connects to the terminal T111.

The fourth attenuation circuit 110 has an input terminal (not shown), an output terminal (not shown), and an external control terminal CNTR2. Controlling the external control terminal CNTR2 would allow the fourth attenuation circuit 110 to arbitrarily vary the ratio of the power level at the input terminal and the power level at the output terminal and then output the signal at the resulting power from the output terminal via the terminal T122 and the terminal T132 to the fourth resonator circuit 108. Note that the input terminal of the fourth attenuation circuit 110 connects to the terminal T112.

The fifth attenuation circuit 113 has an input terminal (not shown), an output terminal (not shown), and an external control terminal CNTR3. Controlling the external control signal CNTR3 would allow the fifth attenuation circuit 113 to arbitrarily vary the ratio of the power level at the input terminal and the power level at the output terminal and then output the signal at the resulting power from the output terminal via the terminal T123 to the second phase shift circuit 115. Note that the input terminal of the fifth attenuation circuit 113 connects to the terminal T113.

The sixth attenuation circuit 114 has an input terminal (not shown), an output terminal (not shown), and an external control terminal CNTR4. Controlling the external control signal CNTR4 would allow the sixth attenuation circuit 114 to arbitrarily vary the ratio of the power level at the input terminal and the power level at the output terminal and then output the signal at the resulting power from the output terminal via the terminal T124 to the third phase shift circuit 116. Note that the input terminal of the sixth attenuation circuit 114 connects to the terminal T114.

The second phase shift circuit 115 has an input terminal (not shown) and an output terminal (not shown). The second phase shift circuit 115 provides a phase shift of (π+θ3) to an input signal supplied to the input terminal via the terminal T123 and then outputs the phase-shifted signal from the output terminal via the terminal T133 to the second compensation circuit 117.

The third phase shift circuit 116 has an input terminal (not shown) and an output terminal (not shown). The third phase shift circuit 116 provides a phase shift of (π+θ4) to an input signal supplied to the input terminal via the terminal T124 and then outputs the phase-shifted signal from the output terminal via the terminal T134 to the third compensation circuit 118.

The third resonator circuit 107 connects to the terminal T131 and a terminal T141 and delivers the output therefrom to the output terminal 4 via the terminal T141 and the power adder circuit 6. The third resonator circuit 107 is configured to have a crystal oscillator X1 disposed between the terminal T131 and the terminal T141.

The fourth resonator circuit 108 connects to the terminal T132 and a terminal T142 and delivers the output therefrom to the output terminal 4 via the terminal T142 and the power adder circuit 6. The fourth resonator circuit 108 is configured to have a crystal oscillator X2 disposed between the terminal T132 and the terminal T142.

The second compensation circuit 117 connects to the terminal T133 and terminal T143 and delivers the output therefrom to the output terminal 4 via a terminal T143 and the power adder circuit 6. The second compensation circuit 117 is configured to have a parallel circuit of a capacitor CP1 and a resistor RP1 interposed between the terminal T133 and the terminal T143. The second compensation circuit 117 removes an unnecessary component of the third resonator circuit 107, i.e., a parallel capacitance component CO1 and a resistance component R1 of the crystal oscillator X1.

The third compensation circuit 118 connects to the terminal T134 and the terminal T144 and delivers the output therefrom to the output terminal 4 via the terminal T144 and the power adder circuit 6. The third compensation circuit 118 is configured to have a parallel circuit of a capacitor CP2 and a resistor RP2 interposed between the terminal T134 and the terminal T144. The third compensation circuit 118 removes an unnecessary component of the fourth resonator circuit 108, i.e., a parallel capacitance component CO2 and a resistance component R2 of the crystal oscillator X2.

Furthermore, the path from the terminal T111 to the terminal T131 is defined as a third current path 130, the path from the terminal T112 to the terminal T132 as a fourth current path 140, the path from the terminal T113 to the terminal T133 as a second compensation current path 150, and the path from the terminal T114 to the terminal T134 as a third compensation current path 160.

The input signal applied via such a circuit to the input terminal 3 of the antiresonant frequency-varying complex resonant circuit 100 is supplied to the third resonator circuit 107, the fourth resonator circuit 108, the second compensation circuit 117, and the third compensation circuit 118. The power level at that time is as follows.

The level of power applied to each of the third resonator circuit 107 and the fourth resonator circuit 108 is an absolute voltage value of |e1| and |e2|, respectively, in terms of the respective electromotive forces. The input signal supplied at the frequency f from the input terminal 3 has been provided with a 0 (zero) phase shift for the third resonator circuit 107 and the fourth resonator circuit 108. Furthermore, at this time, the terminal T131 and the terminal T132 have an internal resistance of zs1 and zs2, respectively.

The level of power applied to each of the second compensation circuit 117 and the third compensation circuit 118 is an absolute voltage value of |e3| and |e4|, respectively, in terms of the respective electromotive forces. The input signal supplied at the frequency f from the input terminal 3 has been provided with a phase shift of (π+θ3) for the second compensation circuit 117 and a phase shift of (π+θ4) for the third compensation circuit 118. Furthermore, at this time, the terminal T133 and the terminal T134 have an internal resistance of zs3 and zs4, respectively.

That is, the third resonator circuit 107 is equivalent to a series circuit of an equivalent power supply connected to an internal resistor of a resistance value of zs1, the power supply providing the absolute value of electromotive force |e1| with zero phase shift. The fourth resonator circuit 108 is equivalent to a series circuit of an equivalent power supply connected to an internal resistor of a resistance value of zs2, the power supply providing the absolute value of electromotive force |e2| with zero phase shift. The second compensation circuit 117 is equivalent to a series circuit of an equivalent power supply connected to an internal resistor of a resistance value of zs3, the power supply providing the absolute value of electromotive force |e3| with a phase of (π+θ3). The third compensation circuit 118 is equivalent to a series circuit of an equivalent power supply connected to an internal resistor of a resistance value of zs4, the power supply providing the absolute value of electromotive force |e4| with a phase of (π+θ4).

Now, a description will be made to the effects and performance of the second embodiment with reference to the results of numerical simulations. In the first step, it will be described that the effects of parallel capacitance unique to the piezoelectric oscillator can be reduced using the means that can be inferred on the analogy of Patent Literature 2 mentioned above; however, the resonance quality factor Q value of the antiresonant frequency-varying complex resonant circuit 100 will not be increased to such an extent as expected. In the second step, it will be described that the compensation circuit shown in the second embodiment can significantly improve the resonance quality factor Q value. In the third step, it will be described that the resistance value RC1 and the resistance value RC2 have an optimum value in a narrow range.

The outline of the simulation is as follows. The simulation was performed on the assumption that in a variable frequency range of 1000 ppm (from 9995 kHz to 10005 kHz) with a center frequency of 10 MHz, the electromotive forces and the internal resistances of the equivalent power supplies connected equivalently to the terminal T131 and the terminal T133 are equal to each other, while the electromotive forces and the internal resistances of the equivalent power supplies connected equivalently to the terminal T132 and the terminal T134 are also equal to each other.

To perform the simulation, the third resonator circuit 107 and the fourth resonator circuit 108 were provided with the equivalent circuit constants shown in Table 2. The second compensation circuit 117 and the third compensation circuit 118 were provided with the equivalent circuit constants shown in Table 3.

TABLE 2

| THIRD RESONATOR CIRCUIT | FOURTH RESONATOR CIRCUIT |
|---|---|
| f1 = 9995 kHz | f2 = 10005 kHz |
| L1 = 25.306 mH | L2 = 25.745 mH |
| C1 = 10.04976 fF | C2 = 9.799681 fF |
| R1 = 10.13 Ω | R2 = 11.311 Ω |
| C01 = 3.619 pF | C02 = 3.8237 pF |
| Z_{S1} = 50 Ω | Z_{S2} = 50 Ω |

z₁ = 50 Ω

TABLE 3

| SECOND | |
|---|---|
| COMPENSATION CIRCUIT | THIRD COMPENSATION CIRCUIT |
| CP1 = 3.6 pF | CP2 = 3.6 pF |
| RP1 = 41 kΩ | RP2 = 41 kΩ |

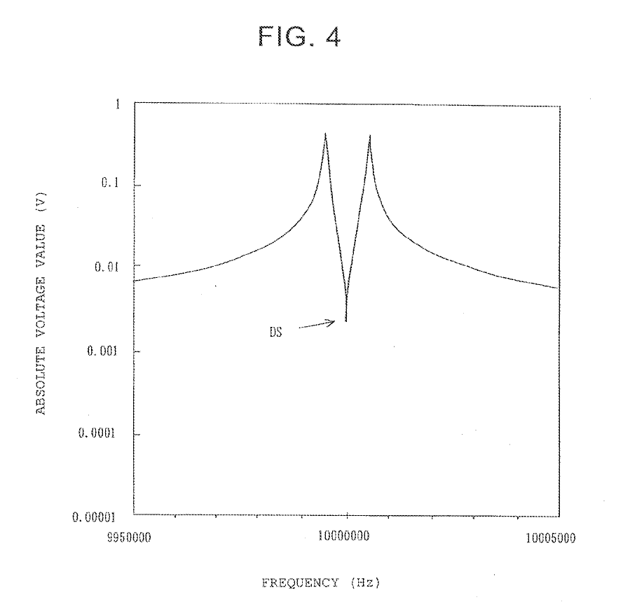

A description will be made to the results of the simulation in the first step with reference to FIG. 4. For the simulation, the voltages applied to the terminal T131 to terminal 134 were all equal to 1 V. Furthermore, both the values of part of phase shift θ3 and part of phase shift θ4 were set to 0. Note that in FIG. 4, the horizontal axis represents the frequency (Hz) and the vertical axis represents the absolute value of a voltage established across the ends of the load resistance zl.

Furthermore, the resistors RP1 and RP2, which constitute the second compensation circuit 117 and the third compensation circuit 118 of FIG. 3, respectively, were set to infinity, and both the capacitor CP1 and the capacitor CP2 were set to 3.6 pF, thereby simulating the means that can be inferred on the analogy of Patent Literature 2 mentioned above. From FIG. 4, it will be shown that the influence of a parallel capacitance unique to the piezoelectric oscillator can be alleviated, allowing for exhibiting a single minimum point DS. It will be pointed out that even the conventional technique provides a voltage drop to this extent at the minimum point DS.

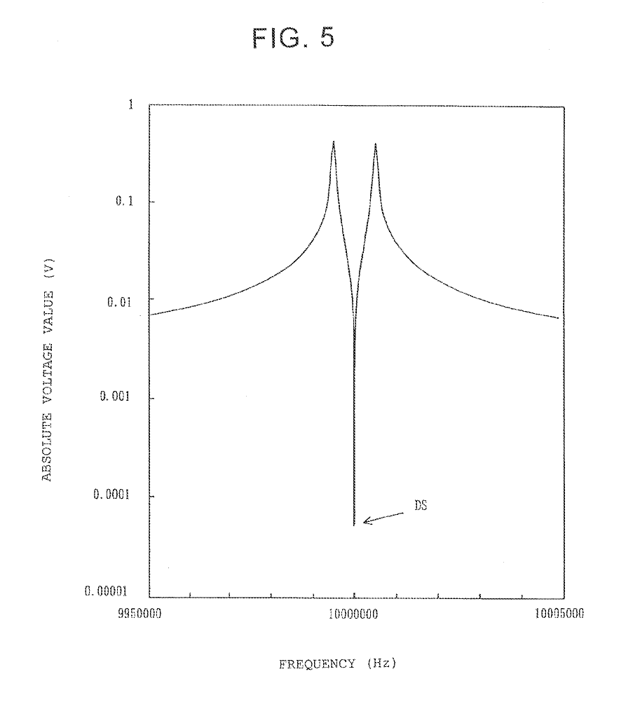

Now, the results of a simulation in the second step will be shown in FIG. 5. As shown in FIG. 5, the capacitors CP1 and CP2 which constitute the second compensation circuit 117 and the third compensation circuit 118 of FIG. 3, respectively, were set to the same value, and while the value was being maintained at a constant value of 3.6 pF, the resistors RP1 and RP2, which constitute the second compensation circuit 117 and the third compensation circuit 118, respectively, were set to the same value and chosen in a wide range in order to perform the simulation. As a result, at 41 kΩ, a sharp drop was found at the relative minimum DS, i.e., a good resonance quality factor Q value was obtained. A comparison between the relative minimum DS of FIG. 5 and the relative minimum DS of FIG. 4 shows nearly two orders of magnitude of improvement. As a result, the resonance quality factor Q value at the DS point is significantly improved. At this time, the resonance quality factor Q value reaches 1000000 or six times the resonance quality factor Q value, 150000, of a single crystal oscillator. It can also be found that a parallel circuit of a capacitor of 3.6 pF and a resistor of 41 kΩ employed as the compensation circuit would not have an adverse effect on the characteristics of the series arm of the crystal oscillator.

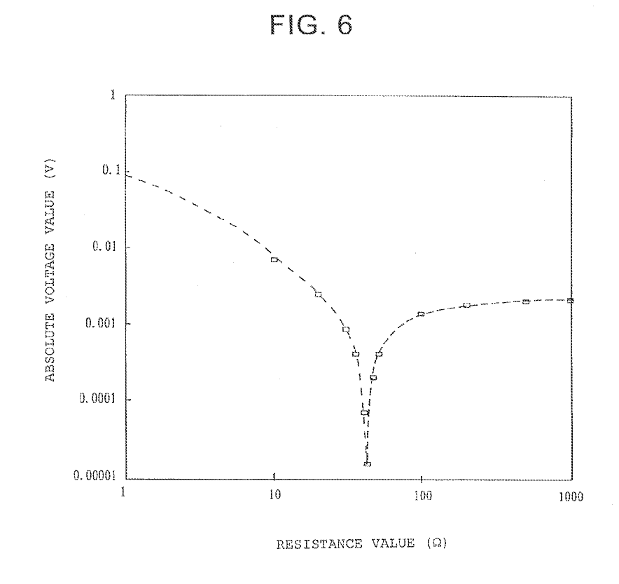

Finally, the results of a simulation in the third step are shown in FIG. 6. To obtain such an effect as the results of compensation shown in FIG. 5, it is necessary to compensate 10Ω, or the value of the series resistor R1 and the series resistor R2, which is a factor that determines the resonance quality factor Q value of the crystal oscillator X1 of the third resonator circuit 107 and the crystal oscillator X2 of the fourth resonator circuit 108 in FIG. 3. However, according. to the present invention, the second embodiment employed the form of a parallel resistor circuit which simplifies the structure of the compensation circuit, whereby it was found as shown in FIG. 6 that as the value thereof, an optimum value was present at an unexpected value of a parallel resistance of 41 kΩ.

In FIG. 6, the vertical axis represents the absolute value of a voltage (the value of the relative minimum DS) established across the ends of the load resistance zl of FIG. 5, and the horizontal axis represents the value of the resistor RP1 and the resistor RP2 which constitute the second compensation circuit 117 and the third compensation circuit 118, respectively, the resistor RP1 and the resistor RP2 being set to an equal value in kΩ and varied as a parameter. It is shown that varying the resistance value on the horizontal axis from 0Ω to infinite Ω results in an optimum point being present only at 41 kΩ. Furthermore, although not illustrated in FIG. 6, setting the resistance value on the horizontal axis to less than 1 kΩ results in the absolute voltage value on the vertical axis approaching 1 V. Conversely, setting to above 1000 kΩ would result in the value approaching the value of the minimum point DS (0.001) on the vertical axis of FIG. 4, which can be inferred on the analogy of the conventional technique.

This sole 41 kΩ parallel compensation resistance value is an unexpected value for an equivalent resistance value of 10Ω of the crystal oscillator to be compensated. It is thus noteworthy to have discovered that the resonance quality factor Q value obtained by calculating from the frequency characteristics in the vicinity of the frequency which gives the minimum point DS at this time reaches a value that is six times the resonance quality factor Q value of the crystal oscillator itself being employed.

Now, as the third resonator circuit 107 and the fourth resonator circuit 108, a FBAR resonator made of a thin film of aluminum nitride is known to well approximate the resonance characteristics thereof by a parallel circuit which includes a circuit having a series connection of parallel capacitors and a resistor and a series circuit having a series connection of a coil, a capacitor, and a resistor. In such a FRAR resonator, the compensation means of the second embodiment is also effective by appropriately determining the circuit form of the compensation circuit and selecting the circuit constants.

Now, several more modified items employed will be listed below. The resistor and the capacitor which constitute the compensation circuit may also be connected in series. The third attenuation circuit 109 and the fifth attenuation circuit 113 can be shared with the fourth attenuation circuit 110 and the sixth attenuation circuit 114 so as to half the number of the attenuation circuits. The arm that includes the resonator circuit of FIG. 3, for example, the arm of the terminal T111, the terminal T121, the terminal T131, and the terminal T141 may include a phase shift circuit.

### Third Embodiment

FIG. 7 shows an antiresonant frequency-varying complex resonant circuit according to a third embodiment of the present invention. The antiresonant frequency-varying complex resonant circuit 200 of the third embodiment is the antiresonant frequency-varying complex resonant circuit 100 of the second embodiment which further includes two phase shift circuits with the resonator circuit and the compensation circuit modified in structure. Now, a description will be made with reference to FIG. 7.

The antiresonant frequency-varying complex resonant circuit 200 includes a reference terminal 2; an input terminal 3; a seventh attenuation circuit 209 for attenuating the power level of an input signal, which is supplied at a frequency f from the input terminal 3 via a power distribution circuit 5, into a power level e1, and supplying the signal at the resulting power to a fourth phase shift circuit 211 via a terminal T221; an eighth attenuation circuit 210 for attenuating the power level of an input signal, which is supplied at the frequency f from the input terminal 3 via the power distribution circuit 5, into a power level e2, and supplying the signal at the resulting power to a fifth phase shift circuit 212 via a terminal T222; a ninth attenuation circuit 213 for attenuating the power level of an input signal, which is supplied at the frequency f from the input terminal 3 via the power distribution circuit 5, into a power level e3, and supplying the signal at the resulting power to a sixth phase shift circuit 215 via a terminal T223; and a tenth attenuation circuit 214 for attenuating the power level of an input signal, which is supplied at the frequency f from the input terminal 3 via the power distribution circuit 5, into a power level e4, and supplying the signal at the resulting power to a seventh phase shift circuit 216 via the terminal T224. Note that power levels e1, e2, e3, and e4 are different from each other.

Furthermore, the antiresonant frequency-varying complex resonant circuit 200 further includes the fourth phase shift circuit 211 for providing a phase shift of θ1 to a signal supplied at the frequency f from the seventh attenuation circuit 209, and supplying the phase-shifted signal to a fifth resonator circuit 207 via a terminal T231; the fifth phase shift circuit 212 for providing a phase shift of θ2 to a signal supplied at the frequency f from the eighth attenuation circuit 210, and supplying the phase-shifted signal to a sixth resonator circuit 208 via a terminal T232; the sixth phase shift circuit 215 for providing a phase shift of (θ1+π) to a signal supplied at the frequency f from the ninth attenuation circuit 213, and supplying the phase-shifted signal to a fourth compensation circuit 217 via a terminal T233; and the seventh phase shift circuit 216 for providing a phase shift of (θ2+π) to a signal supplied at the frequency f from the tenth attenuation circuit 214, and supplying the phase-shifted signal to a fifth compensation circuit 218 via a terminal T234. Note that the phase shifts θ1, θ2, (θ1+π), and (θ2+π) are different from each other.

Furthermore, the antiresonant frequency-varying complex resonant circuit 200 further includes the fifth resonator circuit 207 connected to the fourth phase shift circuit 211 via the terminal T231; the sixth resonator circuit 208 connected to the fifth phase shift circuit 212 via the terminal T232; the fourth compensation circuit 217 connected to the sixth phase shift circuit 215 via the terminal T233; the fifth compensation circuit 218 connected to the seventh phase shift circuit 216 via the terminal T234; a power adder circuit 6 connected to each of the terminals T241, T242, T243, and T244; and an output terminal 4 connected to the power adder circuit 6.

Each component of the antiresonant frequency-varying complex resonant circuit 200 shown in FIG. 7 will be described in more detail below. The input terminal 3 of the antiresonant frequency-varying complex resonant circuit 200 of FIG. 7 is connected to the standard signal generator SG, so that an input signal, which is maintained at a constant output and has a frequency f continuously swept, is applied to the input terminal 3 of the antiresonant frequency-varying complex resonant circuit 200.

The input signal applied to the input terminal 3 is supplied to the seventh attenuation circuit 209, the eighth attenuation circuit 210, the ninth attenuation circuit 213, and the tenth attenuation circuit 214 via the power distribution circuit 5, and the terminal T211, the terminal T212, the terminal T213, or the terminal T214.

The seventh attenuation circuit 209 has an input terminal (not shown), an output terminal (not shown), and an external control terminal CNTR1. Controlling the external control terminal CNTR1 would allow the seventh attenuation circuit 209 to arbitrarily vary the ratio of the power level at the input terminal and the power level at the output terminal and then output the signal at the resulting power from the output terminal via the terminal T221 to the fourth phase shift circuit 211. Note that the input terminal of the seventh attenuation circuit 209 connects to the terminal T211.

The eighth attenuation circuit 210 has an input terminal (not shown), an output terminal (not shown), and an external control terminal CNTR2. Controlling the external control terminal CNTR2 would allow the eighth attenuation circuit 210 to arbitrarily vary the ratio of the power level at the input terminal and the power level at the output terminal and then output the signal at the resulting power from the output terminal via the terminal T222 to the fifth phase shift circuit 212. Note that the input terminal of the eighth attenuation circuit 210 connects to the terminal T212.

The ninth attenuation circuit 213 has an input terminal (not shown), an output terminal (not shown), and an external control terminal CNTR3. Controlling the external control signal CNTR3 would allow the ninth attenuation circuit 213 to arbitrarily vary the ratio of the power level at the input terminal and the power level at the output terminal and then output the signal at the resulting power from the output terminal via the terminal T223 to the sixth phase shift circuit 215. Note that the input terminal of the ninth attenuation circuit 213 connects to the terminal T213.

The tenth attenuation circuit 214 has an input terminal (not shown), an output terminal (not shown), and an external control terminal CNTR4. Controlling the external control signal CNTR4 would allow the tenth attenuation circuit 214 to arbitrarily vary the ratio of the power level at the input terminal and the power level at the output terminal and then output the signal at the resulting power from the output terminal via the terminal T224 to the seventh phase shift circuit 216. Note that the input terminal of the tenth attenuation circuit 214 connects to the terminal T214.

The fourth phase shift circuit 211 has an input terminal (not shown) and an output terminal (not shown). The fourth phase shift circuit 211 provides a phase shift of θ1 to an input signal supplied to the input terminal via the terminal T221, and then outputs the phase-shifted signal from the output terminal via the terminal T231 to the fifth resonator circuit 207.

The fifth phase shift circuit 212 has an input terminal (not shown) and an output terminal (not shown). The fifth phase shift circuit 212 provides a phase shift of θ2 to an input signal supplied to the input terminal via the terminal T222, and then outputs the phase-shifted signal from the output terminal via the terminal T232 to the sixth resonator circuit 208.

The sixth phase shift circuit 215 has an input terminal (not shown) and an output terminal (not shown). The sixth phase shift circuit 215 provides a phase shift of (θ1+π) to an input signal supplied to the input terminal via the terminal T223, and then outputs the phase-shifted signal from the output terminal via the terminal T233 to the fourth compensation circuit 217.

The seventh phase shift circuit 216 has an input terminal (not shown) and an output terminal (not shown). The seventh phase shift circuit 216 provides a phase shift of (θ2+π) to an input signal supplied to the input terminal via the terminal T224, and then outputs the phase-shifted signal from the output terminal via the terminal T234 to the fifth compensation circuit 218.

The fifth resonator circuit 207 connects to the terminal T231, the terminal T241, and the reference terminal 2, and delivers the output therefrom via the terminal T241 and the power adder circuit 6 to the output terminal 4. The fifth resonator circuit 207 is configured to have a series circuit of a coil LS1 and a capacitor CS1 disposed between the terminal T231 and the terminal T241, and the crystal oscillator X1 disposed between the intermediate point (connection point) of the series circuit and a reference potential 2.

The sixth resonator circuit 208 connects to the terminal T232, the terminal T242, and the reference terminal 2, and delivers the output therefrom via the terminal T242 and the power adder circuit 6 to the output terminal 4. The sixth resonator circuit 208 is configured to have a series circuit of a coil LS2 and a capacitor CS2 disposed between the terminal T232 and the terminal T242, and the crystal oscillator X2 disposed between the intermediate point (connection point) of the series circuit and the reference potential 2.

The fourth compensation circuit 217 connects to the terminal T233, the terminal T243, and the reference terminal 2, and delivers the output therefrom via the terminal T243 and the power adder circuit 6 to the output terminal 4. The fourth compensation circuit 217 is configured to have a series circuit of a coil LS1′ and a capacitor CS1′ disposed between the terminal T233 and the terminal T243, and the resistor RC1 disposed between the intermediate point (connection point) of the series circuit and the reference potential 2. The fourth compensation circuit 217 removes an unnecessary component of the fifth resonator circuit 207, i.e., the resistance component R1 of the crystal oscillator X1.

The fifth compensation circuit 218 connects to the terminal T234, the terminal T244, and the reference terminal 2, and delivers the output therefrom via the terminal T244 and the power adder circuit 6 to the output terminal 4. The fifth compensation circuit 218 is configured to have a series circuit of a coil LS2′ and a capacitor CS2′ disposed between the terminal T234 and the terminal T244, and the resistor RC2 disposed between the intermediate point (connection point) of the series circuit and the reference potential 2. The fifth compensation circuit 218 removes an unnecessary component of the sixth resonator circuit 208, i.e., the resistance component R2 of the crystal oscillator X2.

Furthermore, the path from the terminal T211 to the terminal T231 is defined as a fifth current path 230, the path from the terminal T212 to the terminal T232 as a sixth current path 240, the path from the terminal T213 to the terminal T233 as a fourth compensation current path 250, and the path from the terminal T214 to the terminal T234 as a fifth compensation current path 260.

The input signal applied to the input terminal 3 of the antiresonant frequency-varying complex resonant circuit 200 via such circuits is supplied to each of the fifth resonator circuit 207, the sixth resonator circuit 208, the fourth compensation circuit 217, and the fifth compensation circuit 218. The power level at that time is as follows.

The level of power applied to each of the fifth resonator circuit 207 and the sixth resonator circuit 208 is an absolute voltage value of |e1| and |e2|, respectively, in terms of the respective electromotive forces. The input signal applied to the input terminal 3 has been provided with a phase shift of θ1 for the fifth resonator circuit 207 and a phase shift of θ2 for the sixth resonator circuit 208. Furthermore, at this time, the terminal T231 and the terminal T232 have an internal resistance of zs1 and zs2, respectively.

The level of power applied to each of the fourth compensation circuit 217 and the fifth compensation circuit 218 is an absolute voltage value of |e3| and |e4|, respectively, in terms of the respective electromotive forces. The input signal applied to the input terminal 3 has been provided with a phase shift of (θ1+π) for the fourth compensation circuit 217 and a phase shift of (θ2+π) for the fifth compensation circuit 218. Furthermore, at this time, the terminal T233 and the terminal T234 have an internal resistance of zs3 and zs4, respectively.

That is, the fifth resonator circuit 207 is equivalent to a series circuit of an equivalent power supply connected to an internal resistor of a resistance value of zs1, the power supply providing the absolute value of electromotive force |e1| with a phase of θ1. The sixth resonator circuit 208 is equivalent to a series circuit of an equivalent power supply connected to an internal resistor of a resistance value of zs2, the power supply providing the absolute value of electromotive force |e2| with a phase of θ2. The fourth compensation circuit 217 is equivalent to a series circuit of an equivalent power supply connected to an internal resistor of a resistance value of zs3, the power supply providing the absolute value of electromotive force |e3| with a phase of (θ1+π). The fifth compensation circuit 218 is equivalent to a series circuit of an equivalent power supply connected to an internal resistor of a resistance value of zs4, the power supply providing the absolute value of electromotive force |e4| with a phase of (θ2+π).

Now, the effects and performance of the third embodiment will be explained in three steps referring to the results of numerical simulations.

In the first step, it will be described that in the method of the third embodiment which does not include the fourth compensation circuit 217 and the fifth compensation circuit 218, deterioration in the resonance quality factor Q value cannot be ignored at the ends of the variable frequency range. In the second step, it will be described that the compensation circuit of the present invention provides a significant improvement in the resonance quality factor Q value at the ends. In the third step, such a case will be illustrated in which the effective resonance quality factor Q value under an actual operating condition over the entire variable frequency range is so set as to be maintained about at the same value as the resonance quality factor Q value of the single crystal oscillator employed.

The outline of the simulation is as follows. The simulation was performed on the assumption that in a variable frequency range of 4000 ppm (from 9980 kHz to 10020 kHz) with a center frequency of 10 MHz, the electromotive forces and the internal resistances of the equivalent power supplies connected equivalently to the terminal T231 and the terminal T233 are equal to each other, while the electromotive forces and the internal resistances of the equivalent power supplies connected equivalently to the terminal T232 and the terminal T234 are equal to each other.

For the simulation to be performed, the fifth resonator circuit 207 and the sixth resonator circuit 208 were provided with the equivalent circuit constants shown in Table 4. The fourth compensation circuit 217 and the fifth compensation circuit 218 were provided with the equivalent circuit constants shown in Table 5.

TABLE 4

| FIFTH RESONATOR CIRCUIT | SIXTH RESONATOR CIRCUIT |
|---|---|
| f1 = 9980 kHz | f2 = 10020 kHz |
| L1 = 25.306 mH | L2 = 25.745 mH |
| C1 = 10.04976 fF | C2 = 9.799681 fF |
| R1 = 10.13 Ω | R2 = 11.311 Ω |
| C01 = 3.619 pF | C02 = 3.8237 pF |
| LS1 = 21.392 μH | LS2 = 21.392 μH |
| CS1 = 8.200 pF | CS2 = 8.17 pF |
| Z_{S1} = 34.68 Ω | Z_{S2} = 33.85 Ω |

z₁ = 50 Ω

TABLE 5

| FOURTH | |
|---|---|
| COMPENSATION CIRCUIT | FIFTH COMPENSATION CIRCUIT |
| f1 = 9980 kHz | f2 = 10020 kHz |
| LS1′ = 21.392 μH | LS2′ = 21.392 μH |
| CS1′ = 11.819 pF | CS2′ = 11.8407 pF |
| RC1 = 2.5 Ω | RC2 = 2.5 Ω |

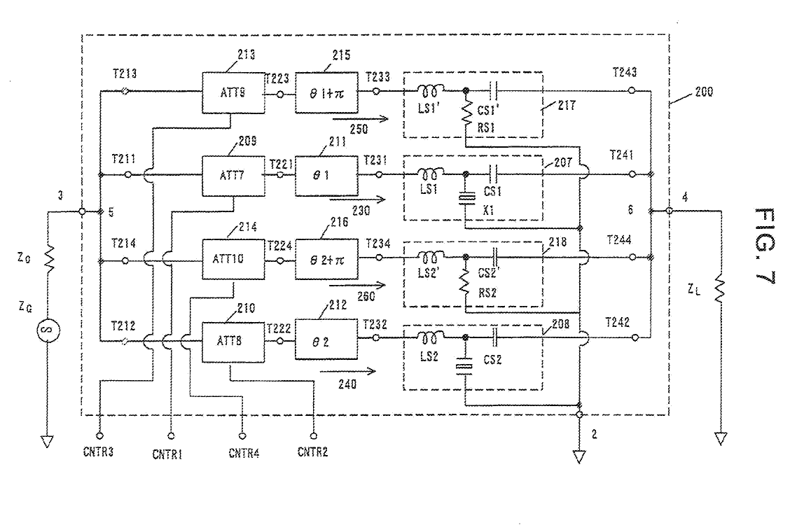

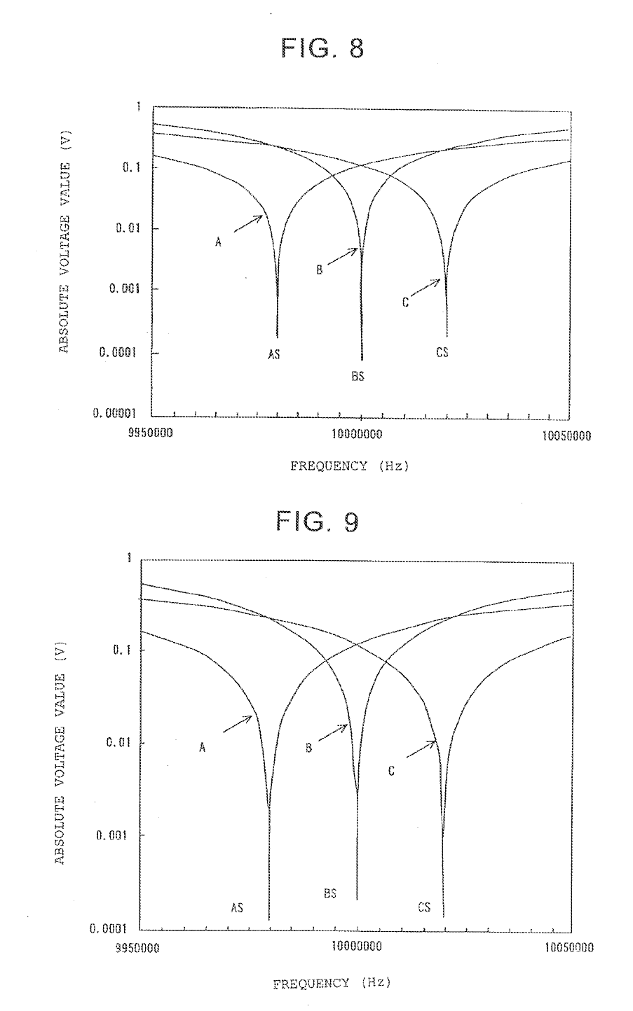

Referring to FIG. 8, a description will be made to the results of the simulation in the first step. For the simulation, both the voltages applied to the terminal T233 and the terminal T234 were 0 V, while as for the phase shifts, the phase shift θ1 provided by the fourth phase shift circuit 211 was +7°, the phase shift θ2 provided by the fifth phase shift circuit 212 was −7°, the phase shift (θ1+π) provided by the sixth phase shift circuit 215 was +187°, and the phase shift (θ2+π) provided by the seventh phase shift circuit 216 was +173°.

In FIG. 8, the horizontal axis represents the frequency (Hz) and the vertical axis represents the absolute value of a voltage established across the ends of the load resistance zl. In this simulation, a numerical experiment was performed by setting an increased amount of attenuation for the ninth attenuation circuit 213 and the tenth attenuation circuit 214 of FIG. 7. This caused the fourth compensation circuit 217 and the fifth compensation circuit 218 to be supplied with zero applied voltage and allowed no current to flow into the power adder circuit 6, thereby preventing the operation of the fourth compensation circuit 217 and the fifth compensation circuit 218 which are to implement the effects of this third embodiment.

The three curves A, B, and C of FIG. 8 represent the cases where the voltage e1 to be applied to the terminal T231 and the voltage e2 to be applied to the terminal T232 were set to 1 V and 0 V, 1 V and 1 V, and 0 V and 1 V, respectively. The three curves have relative minima AS, BS, and CS, respectively, where the two minima, i.e., the relative minimum AS and the relative minimum CS, have a less voltage drop at those relative minima when compared with the relative minimum BS located near the center frequency. At first glance, this shows that the resonance quality factor Q value has deteriorated to such an extent that cannot be ignored. In the next step, the degree of this deterioration is improved by allowing the two compensation circuits of FIG. 7 to function.

Now, the simulation of the second step shown in FIG. 9 was performed by equally setting the electromotive force of the equivalent power supply at both the terminal T231 and the terminal T233 of FIG. 7 and by equally setting the electromotive force of the equivalent power supply at both the terminal T232 and the terminal T234, with the same phase shift as in the case of FIG. 8, i.e., with the phase shift θ1 of the fourth phase shift circuit 211 being +7°, the phase shift θ2 of the fifth phase shift circuit 212 being −7°, the phase shift (θ1+π) of the sixth phase shift circuit 215 being +187°, and the phase shift (θ2+π) of the seventh phase shift circuit 216 being +173°. In this case, the two resistors RC1 and RC2 of the compensation circuits were set to 10Ω.

In FIG. 9, the horizontal axis represents the frequency (Hz) and the vertical axis represents the absolute value of a voltage established across the ends of the load resistance zl. It can be seen that the degree of voltage drop at both ends is abrupt at the relative minimum AS and the relative minimum CS on the vertical axis when compared with the relative minimum BS at the center. Here, near one of the two relative minima at both ends, for example, in the vicinity of the relative minimum AS, the quotient (i.e., the resonance quality factor Q value) obtained by dividing the frequency, which gives the relative minimum, by the difference between two frequencies (hereinafter referred to as the 3 dB bandwidth) which provides the relative minimum with a value twice as large as the minimum value reaches 1.8 million. This value exceeds 0.15 million, by an order of magnitude, which is the resonance quality factor Q value (i.e., an unloaded Q value) of the single crystal oscillator that constitutes the fifth resonator circuit 207. This operation can be interpreted such that since the fourth compensation circuit 217 was provided with a setting of 10Ω which is generally the same as the value of the equivalent series resistor R1 of the crystal oscillator which constitutes the resonator circuit, the loss (resistance) component was cancelled out and thereby substantially nearly completely compensated for at the point of addition of the power adder circuit 6. Note that for example, the frequency computed from LS1′ and CS1′ shown in Table 5 is consistent with the resonance frequency 9980 kHz of the crystal oscillator.

The resonance quality factor Q value of 1.8 million (i.e., the effective Q value) was obtained under the operating circuit condition, the value exceeding, by an order of magnitude or greater, the resonance quality factor Q value of 0.15 million of the single crystal oscillator incorporated in the resonator circuit. This phenomenon can be interpreted as follows. That is, according to the present invention, it was found that the resonance characteristic of the Null point is substantially the same as the resonance characteristic of a parallel connection circuit of a coil and a capacitor. Furthermore, since this is a phenomenon at the Null point of a bridge balance, it is conceivably reasonable to exceed the resonance quality factor Q value of the crystal oscillator which constitutes the bridge circuit.

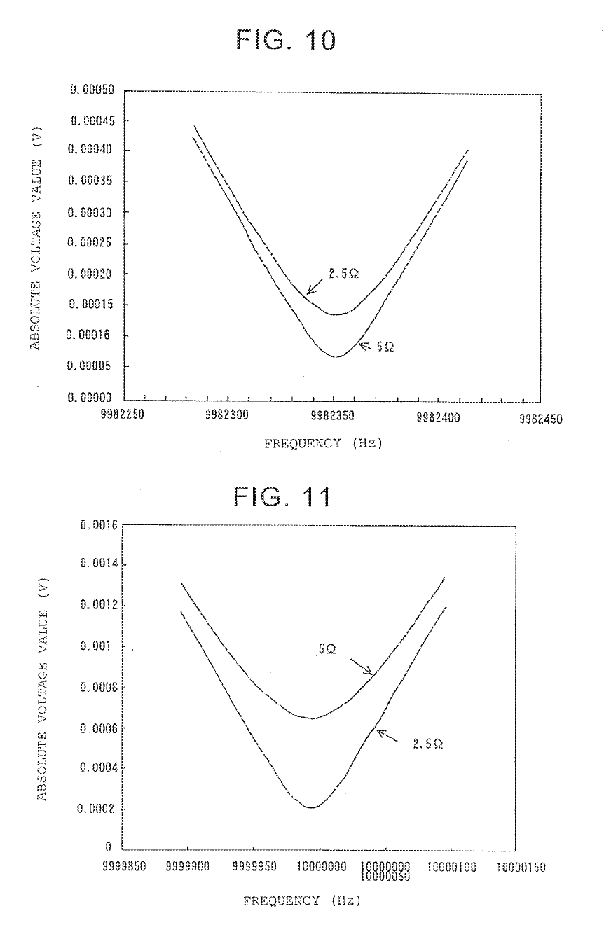

Finally, the results of a simulation in the third step will be shown in FIGS. 10 and 11. In this step, to obtain a constant resonance quality factor Q value across the entire variable frequency range, the values of the shunt resistances of the compensation circuits, i.e., the resistance value RC1 and the resistance value RC2 were varied as a parameter for the simulation so as to provide the optimum settings.

In FIGS. 10 and 11, to determine the resonance quality factor Q value, the resonance characteristics in the vicinity of the respective relative minima are shown under magnification, the horizontal axis representing the frequency, the vertical axis representing the absolute value of a voltage established across the ends of the load resistance zl. In FIG. 10, to obtain the Null frequency near the lower end of the variable frequency range, the voltage ratios at the terminal T231 and the terminal T233 as well as at the terminal T232 and the terminal T234 are each 1:0.0625. The resonance characteristics were determined in two ways with the shunt resistance values being 5Ω and 2.5Ω. For 2.5Ω, the resonance quality factor Q value is 130000. This value is generally the same as the resonance quality factor Q value of the single crystal oscillator employed.

In FIG. 11, to obtain the Null frequency near the center of the variable frequency range, the voltage ratios at the terminal T231 and the terminal T233 as well as at the terminal T232 and the terminal T234 were each set to be 1:1. The resonance characteristics were determined in two ways with the shunt resistance values being 5Ω and 2.5Ω. For 2.5Ω, the resonance quality factor Q value is 150000. This value is generally the same as the resonance quality factor Q value of the single crystal oscillator employed.

The simulation results thus obtained show that varying the Null frequency over the entire variable frequency range by changing the two applied voltages in a wide range would lead to reduced deterioration in the resonance quality factor Q value across all the frequencies.

As such, it was possible to adjust the values of RC1 and RC2 to thereby keep the resonance quality factor Q value generally constant in the operating condition over the entire variable frequency range. Such resonance quality factor Q values as 130000 and 150000 are generally at the same level as 150000 of the single crystal oscillator, and these numerical values were obtained for the first time by the present invention.

Now, a description will be made to a modified embodiment. That is, the sixth phase shift circuit 215 may provide a phase shift of (θ1+π) in the combination of a phase shift circuit for providing a phase shift of θ1 and a phase reversal amplifier circuit for providing a phase shift of π or a phase reversal transformer or the like.

Furthermore, between the input terminal 3 and the output terminal 4, the order of sequence of the attenuation circuit, the phase shift circuit, and the resonator circuit as well as the order of sequence of the attenuation circuit, the phase shift circuit, and the compensation circuit can be arbitrary, so that the performance of the present invention does not depend on those orders of sequence. The performance of the present invention does not depend on the order of sequence of the coil and the capacitor which constitute the resonator circuit. The phase shift circuit may be implemented by, e.g., a combined circuit of a resistor and a capacitor, a combined circuit of a resistor and an inductive element, a combined circuit of a capacitor and an inductive element, or a delay circuit. Any attenuation circuit may be an amplifier circuit with a variable (gain controllable) amplification factor. When a reversed-phase adder circuit like a differential-input operational amplifier is employed as the power adder circuit, it may be acceptable to employ, as the power distribution circuit, a push-pull-output-like differential-output distribution circuit which has differential-output terminals. The inductive element like a coil may be an element which is equivalently expressed by an active circuit and a resistor. It is possible to widen the variable frequency range by increasing the number of arms including the resonator circuit between the input terminal 3 and the output terminal 4. The antiresonant frequency-varying complex resonant circuit can be arranged in a series connection, thereby providing an improvement in the quality factor of the frequency selection characteristics of the entire antiresonant frequency-varying complex resonant circuit.

### REFERENCE SIGNS LIST

1 complex resonant circuit
2 reference terminal
3 input terminal
4 output terminal
5 power distribution circuit
6 power adder circuit
SG standard signal generator
Z0 impedance of standard signal generator
f frequency outputted by standard signal generator SG
7 first resonator circuit
8 second resonator circuit
9 first attenuation circuit
10 second attenuation circuit
11 first phase shift circuit
zl load resistance
CNTR1, CNTR2 control terminal
17 first compensation circuit

1. An antiresonant frequency-varying complex resonant circuit, comprising:
a first current path on which first gain control is provided to an AC power signal being supplied;
at least one second current path on which second gain control different in an amount of control from the first gain control is provided to the AC power signal;
at least two resonant circuits which are provided each on the respective first and second current paths and which have mutually different resonance points or antiresonance points for the AC power signals passing through the respective first and second current paths and capture the respective AC power signals;
at least one compensation current path on which a compensation phase shift is provided to the AC power signal;
a compensation circuit, provided on the compensation current path, for removing an unnecessary component of the resonant circuit; and
an analog operational circuit for performing analog addition or subtraction on the AC power signal having passed through the first current path, the second current path, and the compensation current path.

2. The antiresonant frequency-varying complex resonant circuit according to claim 1, wherein the compensation current path further provides compensation gain control to the AC power signal.

3. The antiresonant frequency-varying complex resonant circuit according to claim 1, wherein the amounts of the first gain control, the second gain control, and the compensation gain control are variable.

4. The antiresonant frequency-varying complex resonant circuit according to claim 1, wherein the first and second current paths further include first and second phase shift circuits for providing first and second phase shifts, respectively.

5. The antiresonant frequency-varying complex resonant circuit according to claim 4, wherein the first and second phase shifts are variable.

6. An antiresonant frequency-varying complex resonant circuit, comprising:
a first current path on which first gain control is provided to an AC power signal being supplied;
a second current path on which the AC power signal is relayed;
at least two resonant circuits which are provided on the respective first and second current paths and which have mutually different resonance points or antiresonance points for the AC power signals passing through the respective first and second current paths and capture the respective AC power signals;
at least one compensation current path on which a compensation phase shift is provided to the AC power signal;
a compensation circuit, provided on the compensation current path, for removing an unnecessary component of the resonant circuit; and
an analog operational circuit for performing analog addition or subtraction on the AC power signal having passed through the first current path, the second current path, and the compensation current path.

7. The antiresonant frequency-varying complex resonant circuit according to claim 2, wherein the amounts of the first gain control, the second gain control, and the compensation gain control are variable.

8. The antiresonant frequency-varying complex resonant circuit according to claim 2, wherein the first and second current paths further include first and second phase shift circuits for providing first and second phase shifts, respectively.

9. The antiresonant frequency-varying complex resonant circuit according to claim 3, wherein the first and second current paths further include first and second phase shift circuits for providing first and second phase shifts, respectively.

10. The antiresonant frequency-varying complex resonant circuit according to claim 7, wherein the first and second current paths further include first and second phase shift circuits for providing first and second phase shifts, respectively.

11. The antiresonant frequency-varying complex resonant circuit according to claim 8, wherein the first and second phase shifts are variable.

12. The antiresonant frequency-varying complex resonant circuit according to claim 9, wherein the first and second phase shifts are variable.

13. The antiresonant frequency-varying complex resonant circuit according to claim 10, wherein the first and second phase shifts are variable.
